(19) United States
(12) Patent Application Publication
(10) Pub. No.: US 2026/0255559 A1
(43) Pub. Date: Aug. 27, 2026

(54) LIGHT-DRIVEN FREQUENCY-BAND TUNABLE ELECTROMAGNETIC SHIELDING DEVICE

(71) Applicant: Anhui University, Hefei City (CN)

(72) Inventors: Yingsong LI, Hefei City (CN); Yancheng ZHU, Hefei City (CN); Adrian Bekasiewicz, Gdansk (PL)

(21) Appl. No.: 19/537,460

(22) Filed: Feb. 11, 2026

(30) Foreign Application Priority Data
Feb. 24, 2025 (CN) 202510204266.6

(51) Int. Cl. H05K 9/00; H10F 39/18

(52) U.S. Cl. CPC H05K 9/00; H05K 9/0083; H05K 9/0088; H05K 9/009; H10F 39/182

(57) ABSTRACT

A light-driven frequency-band tunable electromagnetic shielding device is provided. The device includes photodiodes, photoresistors, square graphite felt films, polyvinylidene fluoride films, nickel-cobalt alloy films, a grounding metal layer, and a silicon substrate layer. The photodiodes are disposed in holes of the square graphite felt films and around the electromagnetic shielding device. Ends of the photodiodes are directly connected to ends of the photoresistors, and other ends of the photodiodes are connected to the square graphite felt films. Other ends of the photoresistors are connected to the grounding metal layer. The polyvinylidene fluoride films are adhered with the square graphite felt films, and the square graphite felt films are adhered with the nickel-cobalt alloy films. The polyvinylidene fluoride films are adhered to the grounding metal layer, and the grounding metal layer is adhered to the silicon substrate layer.

### CROSS-REFERENCE TO RELATED APPLICATIONS

This application claims priority to Chinese Patent Application No. 202510204266.6, filed on Feb. 24, 2025, the contents of which are hereby incorporated by reference.

### TECHNICAL FIELD

The present disclosure belongs to the technical field of electromagnetic wave antenna design and electromagnetic compatibility design, and specifically relates to a light-driven frequency-band tunable electromagnetic shielding device.

### BACKGROUND

With the development of society, mutual interference between electromagnetic signals has become increasingly severe, leading to some sensitive equipment failing to operate normally or experiencing performance degradation. Electromagnetic interference design is based on the operating frequency of the equipment to suppress external signals, ensuring no mutual electromagnetic interference either within the equipment or between different modules of the equipment. With the continuous evolution of wireless communication technologies—progressing from second generation (2G) and third generation (3G) to fourth generation (4G), fifth generation (5G), the Internet of Things, and unique applications in specific frequency bands—mutual interference continues to intensify, making electromagnetic compatibility design increasingly important.

In terms of technology, conventional electromagnetic compatibility design methods primarily include metal shielding or coating with electromagnetic shielding materials, filtering, grounding, optimizing wiring, using anti-interference components such as magnetic beads, or employing methods like grounding, isolation, or absorbing materials to suppress or shield unwanted signals. However, once these methods are designed and implemented, their operating frequency may not be adjusted, or their performance may be inadequate in other frequency bands. Additionally, they require related power supply devices.

Furthermore, electromagnetic shielding technology is also continuously evolving with the advancement of materials and processes. There are new metal-polymer composite materials: such as copper-polypropylene, aluminum-polyethylene; carbon-based polymer composite materials: such as graphene-epoxy resin, carbon nanotube-polyurethane; and multilayer structural materials: which achieve broadband shielding through multilayer design. However, these materials are complex and may not be adjusted according to different frequency requirements. With the increasing refinement of micro-and nano-fabrication processes, electromagnetic shielding may be designed using different electromagnetic structures, featuring smaller sizes and lighter structures. However, current electromagnetic structures need to be designed based on predetermined frequencies. Once designed, their frequencies may not be modified or adjusted, requiring redesign for other frequencies. Therefore, designing structures with smaller electrical dimensions that can be dynamically adjusted according to different electromagnetic frequencies, without requiring voltage consumption, presents a new path for solving electromagnetic shielding problems. The present disclosure develops a light-driven frequency-band tunable electromagnetic shielding device, which may achieve frequency adjustability of the electromagnetic shielding device based on different light intensities, realizing a frequency-band tunable electromagnetic shielding structure to meet the electromagnetic shielding requirements of different scenarios.

### SUMMARY

The present disclosure aims to address the shortcomings of existing technologies and provides the following scheme.

A light-driven frequency-band tunable electromagnetic shielding device includes: photodiodes, photoresistors, square graphite felt films, polyvinylidene fluoride films, nickel-cobalt alloy films, a grounding metal layer, and a silicon substrate layer.

The photodiodes are disposed in holes of the square graphite felt films and around the electromagnetic shielding device. Ends of the photodiodes are directly connected to ends of the photoresistors respectively, and other ends of the photodiodes are respectively connected to the square graphite felt films.

Other ends of the photoresistors are connected to the grounding metal layer.

The polyvinylidene fluoride films are adhered with the square graphite felt films, and the square graphite felt films are adhered with the nickel-cobalt alloy films.

The polyvinylidene fluoride films are adhered to the grounding metal layer, and the grounding metal layer is adhered to the silicon substrate layer.

In some embodiments, 64 polyvinylidene fluoride films, 64 square graphite felt films, and 64 nickel-cobalt alloy films are bonded together from bottom to top, and are electrically connected to the photoresistors and the grounding metal layer, forming the electromagnetic shielding device with a spatially arranged metamaterial array.

In some embodiments, the photodiodes are configured to capture ambient light and convert light energy into electrical energy, and the photoresistors are configured to adjust a magnitude of generated current.

In some embodiments, the square graphite felt films are configured to drive the polyvinylidene fluoride films to operate at a specified frequency under action of current from the photodiodes and the photoresistors, and radiate through the nickel-cobalt alloy films.

Compared with existing technologies, the beneficial effects of the present disclosure are as follows.

The present disclosure uses the photodiodes and photoresistors to change a voltage difference between the square graphite felt films and the grounding metal layer, thereby forming a weak deformation on the surface of the polyvinylidene fluoride films, and a frequency of the deformation is controlled by light intensity. Meanwhile, an operating frequency of the electromagnetic shielding material is consistent with the frequency of the deformation, and together with the nickel-cobalt alloy films to constitute a spatially arranged metamaterial array for electromagnetic suppression to achieve electromagnetic shielding. Changes in light intensity may alter the efficiency of photoelectric conversion, generating different currents. Such changes also modify the voltage difference across the photoresistor, which in turn controls the operating frequency of the polyvinylidene fluoride films, allowing dynamic adjustment of the operating frequency based on light intensity.

The present disclosure requires no radio frequency drive, directly utilizes photoelectric conversion, and achieves dynamic adjustment of the operating frequency of the metamaterial spatial electromagnetic suppression structure through the voltage difference between the photodiodes and the photoresistors, making it suitable for different scenarios, and enabling dynamic adjustment and continuous variation of frequency suppression based on light intensity, thereby meeting the suppression of electromagnetic interference from high to low frequencies and achieving electromagnetic shielding.

### BRIEF DESCRIPTION OF THE DRAWINGS

In order to more clearly illustrate the technical schemes of the present disclosure, the drawings required in the embodiments are briefly introduced below. Apparently, the drawings in the following description are only some embodiments of the present disclosure. For those of ordinary skill in the art, other drawings may be obtained based on these drawings without creative effort.

FIG. 1 is a top view of a device according to an embodiment of the present disclosure.

FIG. 2 is a side view of the device according to the embodiment of the present disclosure.

### DETAILED DESCRIPTION OF THE EMBODIMENTS

The technical solutions in the embodiments of the present disclosure will be clearly and completely described below with reference to the accompanying drawings in the embodiments of the present disclosure. It is apparent that the described embodiments are only a part of the embodiments of the present disclosure, and not all of them. All other embodiments obtained by a person of ordinary skill in the art based on the embodiments of the present disclosure without creative efforts shall fall within the protection scope of the present disclosure.

In order to make the above objectives, features, and advantages of the present disclosure more comprehensible, a further detailed description of the present disclosure is provided below with reference to the accompanying drawings and specific implementation methods.

### Embodiment 1

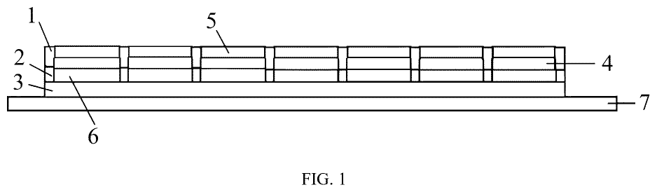

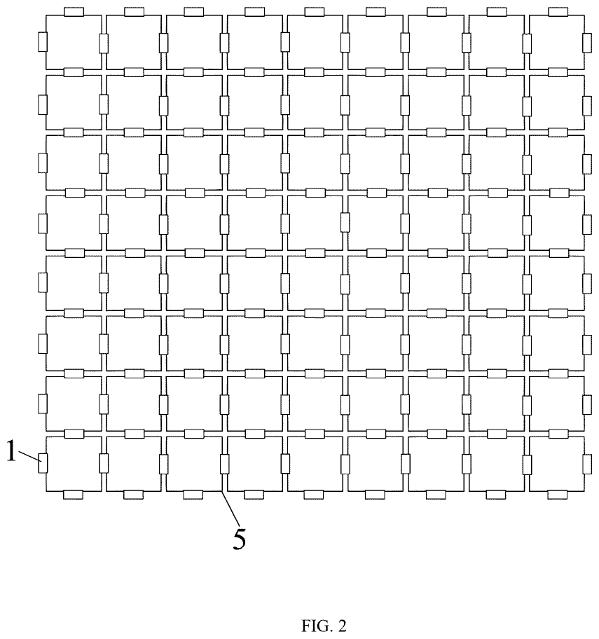

In this embodiment, as shown in FIG. 1 and FIG. 2, a light-driven frequency-band tunable electromagnetic shielding device is provided, including: photodiodes 1, photoresistors 2, square graphite felt films 4, polyvinylidene fluoride films 6, nickel-cobalt alloy films 5, a grounding metal layer 3, and a silicon substrate layer 7.

The photodiodes 1 are disposed in holes of the square graphite felt films 4 and around the electromagnetic shielding device, respectively. One end of each photodiode 1 is directly connected to one end of the corresponding photoresistor 2, and the other end of the photodiode 1 is connected to the square graphite felt film 4. The other end of the photoresistor 2 is connected to the grounding metal layer 3. The nickel-cobalt alloy film 5 is adhered to the square graphite felt film 4, and the square graphite felt film 4 is adhered to the polyvinylidene fluoride film 6. The polyvinylidene fluoride film 6 is adhered to the grounding metal layer 3, and the grounding metal layer 3 is adhered to the silicon substrate layer 7. The grounding metal layer 3 is obtained by a coating method. The photodiode 1 and the photoresistor 2 penetrate through the corresponding nickel-cobalt alloy films 5, the corresponding square graphite felt films 4, and the corresponding polyvinylidene fluoride films 6 to connect with the grounding metal layer 3, and the photodiode 1 is exposed to air through the corresponding hole. The photodiode 1 is configured for capturing ambient light, converting light energy into electrical energy, and the photoresistor 2 is configured for adjusting the magnitude of the generated current. The square graphite felt films 4 is configured to drive the polyvinylidene fluoride film 6 under the action of the current from the photodiode 1 and the photoresistor 2, so as to cause the polyvinylidene fluoride film 6 to operate at a required frequency, and radiate through the nickel-cobalt alloy film 5.

In the embodiment, 64 polyvinylidene fluoride films 6, 64 square graphite felt films 4, and 64 nickel-cobalt alloy films 5 are bonded together from bottom to top, and are electrically connected to the photoresistors 2 and the grounding metal layer 3, so as to form the electromagnetic shielding device with the spatially arranged metamaterial array.

The square graphite felt film 4, under the action of the photodiode 1 together with the photoresistor 2, converts light energy into a voltage difference, which supplies power to the polyvinylidene fluoride film 6 through the square graphite felt film 4. A weak deformation is formed on the surface of the polyvinylidene fluoride film 6, and a frequency of the deformation is controlled by light intensity. Meanwhile, an operating frequency of the electromagnetic shielding material is consistent with the frequency of the deformation, and together with the nickel-cobalt alloy film 5, it constitutes the electromagnetic shielding device with a spatially arranged metamaterial array to achieve electromagnetic shielding. Changes in light intensity may alter the efficiency of photoelectric conversion, generating different currents. Such changes also modify the voltage difference across the photoresistor 2, which in turn controls the operating frequency of the polyvinylidene fluoride film 6, allowing dynamic adjustment of the operating frequency based on light intensity.

### Embodiment 2

In order to solve the problems of repeated design and frequency band limitations in electromagnetic compatibility shielding materials for different broadbands, the present disclosure provides a light-driven frequency-band tunable electromagnetic shielding device, aiming to control the polyvinylidene fluoride films 6 by the photodiodes 1 and the photoresistors 2 under varying light intensity, achieving controllable dynamic frequency and electromagnetic characteristics through the nickel-cobalt alloy films 5. This method may not only meet the dynamic adjustment of frequency, achieve tunable electromagnetic shielding frequency, but also constitute a spatially arranged metamaterial array for electromagnetic suppression, thereby realizing electromagnetic shielding. The device includes: photodiodes 1, photoresistors 2, square graphite felt films 4, polyvinylidene fluoride films 6, nickel-cobalt alloy films 5, a grounding metal layer 3, and a silicon substrate layer 7.

The photodiodes 1 are located around the square graphite felt films 4, the polyvinylidene fluoride films 6, and the nickel-cobalt alloy films 5, as well as around the spatially arranged metamaterial array for electromagnetic suppression, and the photoresistors 2 may be embedded inside the polyvinylidene fluoride films 6 and the nickel-cobalt alloy films 5, directly connecting to the square graphite felt films 4 and the grounding metal layer 3 respectively.

The photodiodes 1 are respectively distributed within holes of the square graphite felt films 4 and around the entire device. Ends of the photodiodes 1 are directly connected to the photoresistors 2, respectively. Ends of the photoresistors 2 are respectively connected to the square graphite felt films 4, and other ends are connected to the grounding metal layer 3. Under changes in light intensity, the voltage difference between the photodiode 1 and the photoelectric terminal changes, forming a dynamically varying voltage difference.

The dynamically varying voltage difference is applied to the upper and lower surfaces of the polyvinylidene fluoride film 6, causing the polyvinylidene fluoride film 6 to produce a weak deformation. A frequency of the deformation is an operating frequency of the spatially arranged metamaterial array for electromagnetic suppression, and this frequency changes with variations in the voltage difference, thereby enabling dynamic broadband tunability.

The square graphite felt film 4 drives the polyvinylidene fluoride film 6 under the action of the current from the photodiode 1 and the photoresistor 2, causing it to operate at a specified frequency, and radiation is performed through the nickel-cobalt alloy film 5. The operating frequency may be controlled by light intensity, and different frequencies may be changed to suit different application scenarios.

In this embodiment, 64 polyvinylidene fluoride films 6, 64 square graphite felt films 4, and 64 nickel-cobalt alloy films 5 are bonded together from bottom to top, and are electrically connected to the photoresistor 2 and the grounding metal layer 3, forming the electromagnetic shielding device with the spatially arranged metamaterial array. Based on the mechanism of electromagnetic structural shielding described above, dynamic control of the frequency may be achieved by controlling the light intensity, thereby realizing the spatially arranged metamaterial array for electromagnetic suppression for different frequency bands and achieving electromagnetic shielding across different frequency bands.

Additionally, under the condition that the photoresistors 2 have identical characteristics, the device in this embodiment may constitute a spatially arranged metamaterial array for electromagnetic suppression, achieving electromagnetic shielding across different frequency bands. However, when the resistance characteristics of the photoresistors 2 are inconsistent, the multiple units, each formed by bonding the polyvinylidene fluoride film 6, square graphite felt film 4, and nickel-cobalt alloy film 5 together from bottom to top, are different antenna units, enabling radiation at different frequencies, and also facilitating the design of continuous broadband antennas.

This embodiment may not only realize a compact metamaterial spatial electromagnetic suppression structure, extremely small multi-frequency antennas, and broadband antennas, covering different frequencies and application scenarios, but also achieve miniaturization and convenience in design, making it highly suitable for occasions with stringent spatial requirements. This embodiment requires no external electrical power energy and may operate directly under light drive, providing a scheme for electromagnetic interference design across multiple frequency bands. Due to changes in light intensity and the control of light intensity, the voltage difference driving the polyvinylidene fluoride film 6 may be controlled, enabling continuous regulation through voltage management. Through electromagnetic conversion by the polyvinylidene fluoride film 6 and the nickel-cobalt alloy film 5, dynamic and continuous control of electromagnetic interference suppression across frequencies is achieved, allowing broadband electromagnetic compatibility management. It is applicable to military and civilian equipment, including computer devices, and may also be used in light-controlled indoor environments to achieve frequency management for smart home devices, as well as in connected vehicles to manage electromagnetic packages. Simultaneously, with its broad-band electromagnetic interference suppression characteristics, the system demonstrates excellent application potential in modern military and communication fields, meeting spectrum demands in novel wireless applications such as suborbital flight, hypersonic equipment, and smart home devices. It may also be used as an antenna in multi-frequency and broadband communication environments, such as smart connected vehicles, smart homes, 5G/sixth generation (6G) mobile communications, and portable communication terminals.

In summary, compared to conventional electromagnetic shielding materials, this embodiment offers tunable functions and frequencies, achieves ultra-broadband electromagnetic interference suppression, and does not require the replacement of electromagnetic equipment. Additionally, through the design of light intensity and the photoresistor 2, multi-band and broadband antenna designs may be realized, enabling continuous regulation across extremely wide frequency ranges and meeting extensive coverage of different operating frequencies.

The embodiments described above are merely illustrative of optional implementations of the present disclosure and do not limit the scope of the disclosure. Without departing from the spirit of the disclosure, various modifications and improvements to the technical schemes of the present disclosure made by those skilled in the art shall fall within the protection scope defined by the claims of the present disclosure.

What is claimed is:

1. A light-driven frequency-band tunable electromagnetic shielding device, comprising:
photodiodes, photoresistors, square graphite felt films, polyvinylidene fluoride films, nickel-cobalt alloy films, a grounding metal layer, and a silicon substrate layer;
wherein the photodiodes are disposed in holes of the square graphite felt films and around the electromagnetic shielding device, ends of the photodiodes are directly connected to ends of the photoresistors, and other ends of the photodiodes are connected to the square graphite felt films;
other ends of the photoresistors are connected to the grounding metal layer;
the polyvinylidene fluoride films are adhered with the square graphite felt films, and the square graphite felt films are adhered with the nickel-cobalt alloy films; and
the polyvinylidene fluoride films are adhered to the grounding metal layer, and the grounding metal layer is adhered to the silicon substrate layer.

2. The light-driven frequency-band tunable electromagnetic shielding device according to claim 1, wherein 64 polyvinylidene fluoride films, 64 square graphite felt films, and 64 nickel-cobalt alloy films are bonded together from bottom to top, and are electrically connected to the photoresistors and the grounding metal layer, so as to form the electromagnetic shielding device with a spatially arranged metamaterial array.

3. The light-driven frequency-band tunable electromagnetic shielding device according to claim 2, wherein the photodiodes are configured to capture ambient light and convert light energy into electrical energy, and the photoresistors are configured to adjust a magnitude of generated current.

4. The light-driven frequency-band tunable electromagnetic shielding device according to claim 2, wherein the square graphite felt films are configured to drive the polyvinylidene fluoride films to operate at a specified frequency under action of current from the photodiodes and the photoresistors, and radiate through the nickel-cobalt alloy films.
